(19) United States
(12) Patent Application Publication
(10) Pub. No.: US 2024/0255269 A1
(43) Pub. Date: Aug. 1, 2024

(54) METHOD OF MANUFACTURING ANGLE SENSORS INCLUDING MAGNETORESISTANCE ELEMENTS INCLUDING DIFFERENT TYPES OF ANTIFERROMAGNETIC MATERIALS

(71) Applicant: Allegro MicroSystems, LLC, Manchester, NH (US)

(72) Inventors: Pablo Nicolás Granell, Ciudad de Buenos Aires (AR); Samridh Jaiswal, London (GB)

(73) Assignee: Allegro MicroSystems, LLC, Manchester, NH (US)

(21) Appl. No.: 18/159,748

(22) Filed: Jan. 26, 2023

(51) Int. Cl. G01B 7/30; G01D 5/16

(52) U.S. Cl. CPC G01B 7/30; G01D 5/16

(57) ABSTRACT

In one aspect, manufacturing a magnetic-field angle sensor includes heating, to a first temperature, a substrate, which includes heating a first magnetoresistance (MR) element including a first type of antiferromagnetic material having a first Néel temperature and a first magnetization direction and heating a second MR element including a second type of antiferromagnetic material having a second Néel temperature and a second magnetization direction. The manufacturing also includes, after heating the substrate to the first temperature, applying a first magnetic field to the substrate in an x-direction to enable a first magnetization direction and a second magnetization direction to be in the x-direction, enabling a temperature of the substrate to be a second temperature and applying a second magnetic field to the substrate in a y-direction to enable the second magnetization direction to be in the y-direction while the first magnetization direction remains in the x-direction.

### BACKGROUND

A magnetic field angle sensor is one example of a magnetic field sensing element. The magnetic field sensing element is used to describe a variety of electronic elements that can sense a magnetic field. The magnetic field sensing element can be, but is not limited to, a Hall Effect element, a magnetoresistance (MR) element, or a magnetotransistor. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge.

Generally, GMR, TMR, and MTJ elements include a reference layer. The magnetization direction of a reference layer determines a direction where the MR element is most sensitive to changes to a magnetic field. The reference layer is generally comprised of a ferromagnetic (FM) layer/antiferromagnetic (AFM) layer system, where the FM layer is directly coupled to the AFM layer via an exchange interaction and is therefore said to be “pinned”. The magnetization direction of the reference layer can be pinned in a desired direction by heating the reference layer to a particular temperature, applying a magnetic field on the reference layer in the desired direction, and subsequently cooling the reference layer in the presence of the magnetic field. This temperature is given as the Néel temperature (T_{N}) of the AFM layer. At the Neel temperature the AF layer transitions from an ordered antiferromagnetic state into a disordered paramagnetic state.

A laser pinning process is a pinning methodology primarily used in two-dimensional (2D) magnetic field angle sensors to pin the magnetization directions of the reference layers for each individual X, Y bridge, which enables the feature of locally setting two distinct directions and obtain a full 0 to 360 degree of functionality on the same die.

### SUMMARY

In one aspect, a method includes manufacturing a magnetic-field angle sensor. The manufacturing includes heating, to a first temperature, a substrate. The heating includes heating a first magnetoresistance (MR) element including a first type of antiferromagnetic material having a first Néel temperature and a first magnetization direction and heating a second MR element including a second type of antiferromagnetic material having a second Néel temperature and a second magnetization direction. The manufacturing also includes, after heating the substrate to the first temperature, applying a first magnetic field to the substrate in an x-direction to enable the first magnetization direction and the second magnetization direction to be in the x-direction, cooling the substrate to a temperature less than the first Néel temperature while applying the first magnetic field, enabling a temperature of the substrate to be a second temperature after ceasing to apply the first magnetic field, and applying a second magnetic field to the substrate in a y-direction to enable the second magnetization direction to be in the y-direction. The first Néel temperature is greater than the second Néel temperature, and the first temperature is greater than the first Néel temperature. The second temperature is less than the first Néel temperature and greater than the second Néel temperature.

In another aspect, a magnetic-field angle sensor includes a first bridge comprising magnetoresistance (MR) elements each comprising a first type of antiferromagnetic material having a first Néel temperature and a first magnetization direction; and a second bridge comprising MR elements comprising a second type of antiferromagnetic material having a second Néel temperature and a second magnetization direction. The first magnetization direction is orthogonal to the second magnetization direction, and the first Néel temperature is higher than the second Néel temperature.

In a further aspect, a method includes manufacturing a magnetic-field angle sensor. The manufacturing includes heating, to a first temperature, a substrate, which includes heating a first magnetoresistance (MR) element comprising a first type of antiferromagnetic material having a first blocking temperature and a first magnetization direction and heating a second MR element comprising a second type of antiferromagnetic material having a second blocking temperature and a second magnetization direction. The manufacturing also includes, after heating the substrate to the first temperature, applying a first magnetic field to the substrate in an x-direction to enable the first magnetization direction and the second magnetization direction to be in the x-direction, cooling the substrate to a temperature less than the first blocking temperature while applying the first magnetic field, enabling a temperature of the substrate to be a second temperature after ceasing to apply the first magnetic field, and applying a second magnetic field to the substrate in a y-direction to enable the second magnetization direction to be in the y-direction. The first blocking temperature is greater than the second blocking temperature, and the first temperature is greater than the first blocking temperature. The second temperature is less than the first blocking temperature and greater than the second blocking temperature.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 is a block diagram of an example of a magnetoresistance (MR) element;

FIGS. 2A to 2C are diagrams depicting setting magnetization directions for two types of antiferromagnetic materials having different Néel temperatures;

FIG. 3 is a flowchart of an example of a process to set magnetization directions for two types of antiferromagnetic materials having different Néel temperatures;

FIGS. 4A to 4D are diagrams depicting setting magnetization directions for three types of antiferromagnetic materials having different Néel temperatures; and

FIG. 5 is a flowchart of an example of a process to set magnetization directions for three types of antiferromagnetic materials Néel temperatures.

### DETAIL DESCRIPTION

Described herein are techniques to fabricate an angle sensor with magnetoresistance (MR) elements having different antiferromagnetic materials. The techniques described herein tune Néel temperatures of antiferromagnetic materials to eliminate a laser repinning process. In one example, the techniques described herein improve the fabrication of MR elements used in a two-dimensional (2D) magnetic field angle sensor. In another example, the techniques described herein improve the fabrication of MR elements used in a three-dimensional (3D) magnetic field angle sensor.

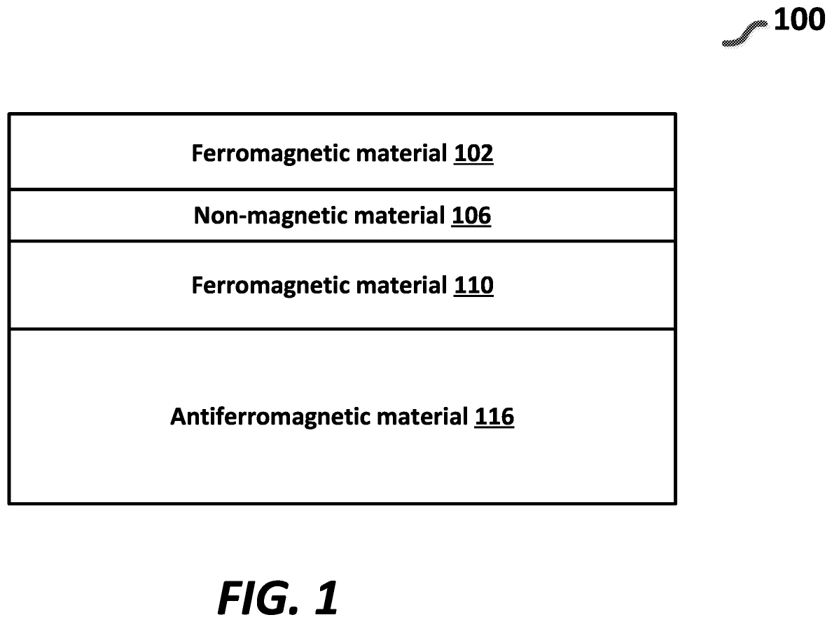

Referring to FIG. 1, an example of a magnetoresistance element is a stack 100. As one of ordinary skill in the art would recognize, FIG. 1 merely shows a simplified diagram of a magnetoresistance element. Other layers may be added to the stack 100 that are not shown in FIG. 1.

The stack 100 includes a ferromagnetic material 102, a ferromagnetic material 110, and a non-magnetic material 106 between the ferromagnetic material 102 and the ferromagnetic material 110. In one example, the non-magnetic material 106 may be a tunneling barrier/spacer (non-magnetic insulator, e.g., MgO) if the stack 100 is a TMR stack. In another example, the non-magnetic material 106 may be a metal (e.g., Cu) if the stack 100 is a GMR stack. The stack 100 also includes an antiferromagnetic material 116 below the ferromagnetic material 110.

In one example, the stack 100 is a spin valve. In one example, the stack is tunneling magnetoresistance (TMR) element. In another example, the stack 100 is a giant magnetoresistance (GMR) element. In a further example, the stack 100 is both a GMR element and a TMR element.

The ferromagnetic material 102 is a free layer and the ferromagnetic material 110 has a pinned magnetization direction. The antiferromagnetic material 116 is a pinning layer. The metal 106 is a non-magnetic spacer.

The ferromagnetic material 110 is directly coupled to the antiferromagnetic material 116 via exchange interaction. The pinning of ferromagnetic material 110 is achieved by heating the structure above the Néel temperature of the antiferromagnetic material 116, applying a magnetic field in the desired pinning direction, and cooling down below the Néel temperature without removing the applied magnetic field. As a result of this magnetic field cooling, the magnetization direction of ferromagnetic material 110 is aligned to the desired direction and pinned by the antiferromagnetic material 116.

Since this procedure is commonly done at the wafer-level in an oven, aligning individual sensing bridges (e.g., cosine bridge (sometimes called herein an x-bridge), sine bridge (sometimes called herein a y-bridge)) is not possible, which is a limiting factor for building angle sensor applications. One possible way to achieve local pinning is to add a repinning process after the first annealing, where a laser heats locally individual MR elements in a bridge and a magnetic field is applied during this process to re-orient them. This, however, is not the most suitable method as repinning involves additional costs in set-up, issues with temperature control and heat dissipation across the wafer via laser heating and requires great control in wafer alignment and laser stability for local re-pinning. Moreover, laser pinning to locally re-pin a stack after the wafer is fabricated causes difficulty in end of line monitoring.

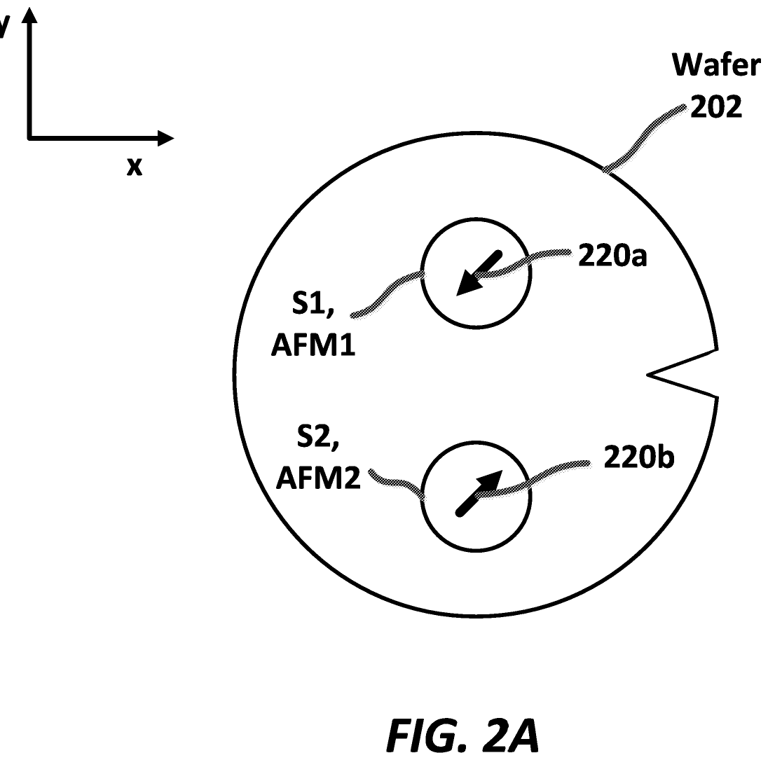

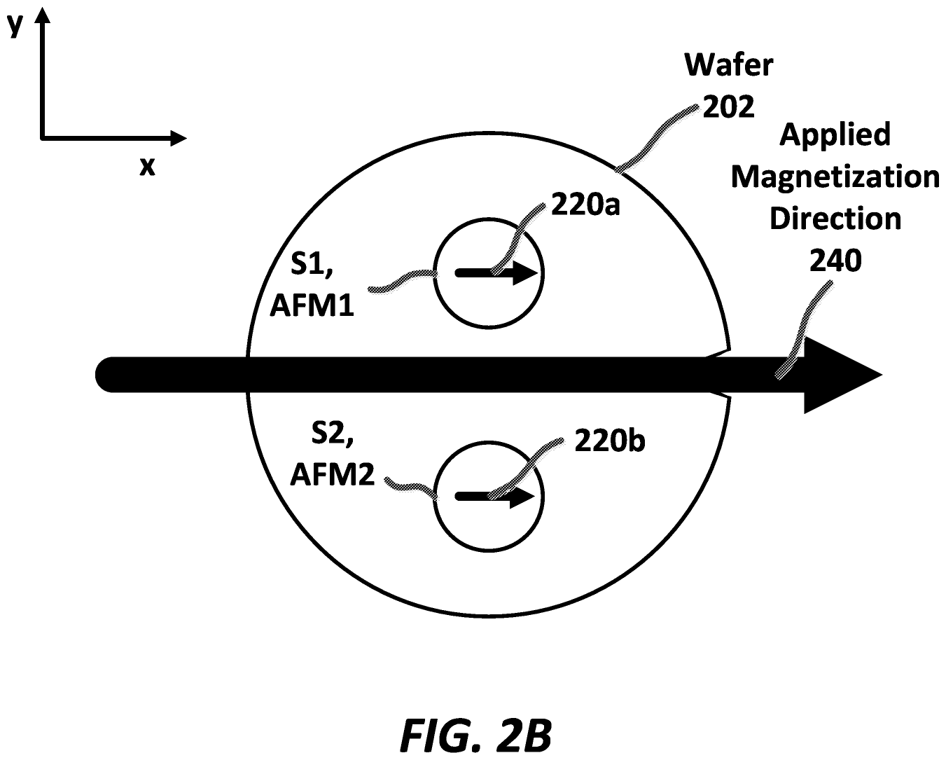

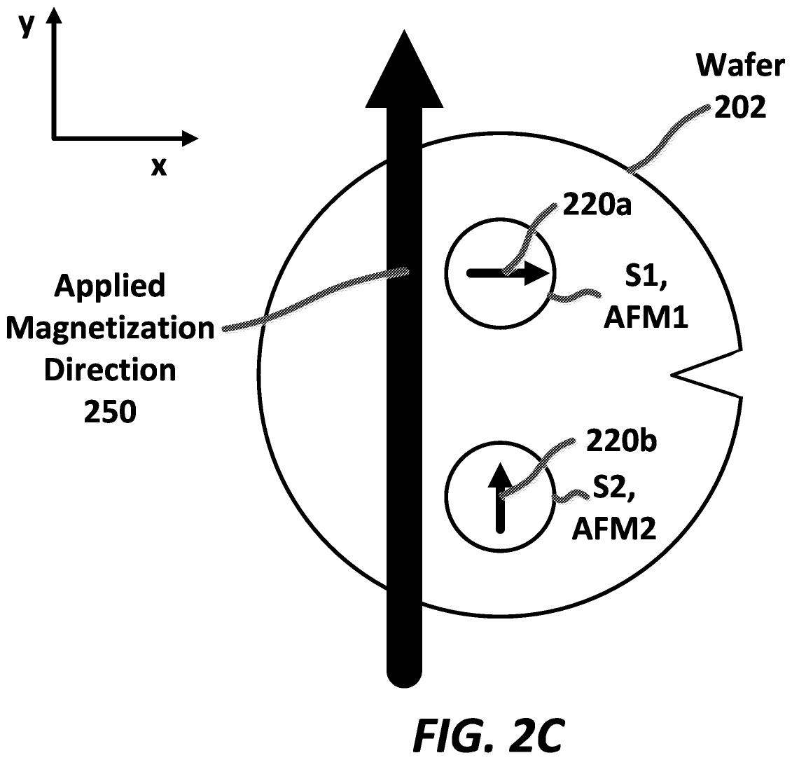

As further described in conjunction with FIGS. 2A to 5, an angle sensor may be fabricated with MR elements having different antiferromagnetic materials by tuning Néel temperatures of the antiferromagnetic materials to eliminate use of laser repinning processes.

Referring to FIG. 2A, a wafer 202 includes a first MR element stack S1 with a first type of antiferromagnetic material (AFM1), and a second MR element stack S2 with a second type of antiferromagnetic material (AFM2). The AFM1 has a Néel temperature T_{N(AF1)} and the AFM2 has a Néel temperature T_{N(AF2)} where T_{N(AF1)}>T_{N(AF2)}. A magnetization direction 220a of the AFM1 and a magnetization direction 220b of the AFM2 are random.

In one example, AFM1 may be iridium manganese (IrMn), iron manganese (FeMn), or platinum manganese (PtMn). In another example, AFM2 may be iridium manganese (IrMn), iron manganese (FeMn), or platinum manganese (PtMn). The examples in the paragraph are limited to T_{N(AF1)}>T_{N(AF2)}.

Referring to FIG. 2B, after heating the wafer 202 to a first temperature greater than T_{N(AF1)}, a magnetic field 240 is applied to the wafer 202 in the x-direction. The magnetization direction 220a of AFM1 and the magnetization direction 220b of AFM2 align with the applied magnetic field 240 and point in the x-direction.

Referring to FIG. 2C, after cooling the wafer 202 and after enabling the temperature of the wafer 202 to be a second temperature greater than T_{N(AF2)} and less than T_{N(AF1)}, a magnetic field 250 is applied to the wafer 202 in the y-direction. The magnetization direction 220b of AFM2 aligns with the applied magnetic field 250 and point in the y-direction, while the magnetization direction 220a of AFM1 remains aligned in the x-direction.

In other examples, additional stacks with AFM1 and AFM2 may be included so that one or more x-bridges and one or more y-bridges may be formed. For example, stacks with AFM1 may be used to form x-bridges and stacks with AFM2 may be used to form y-bridges.

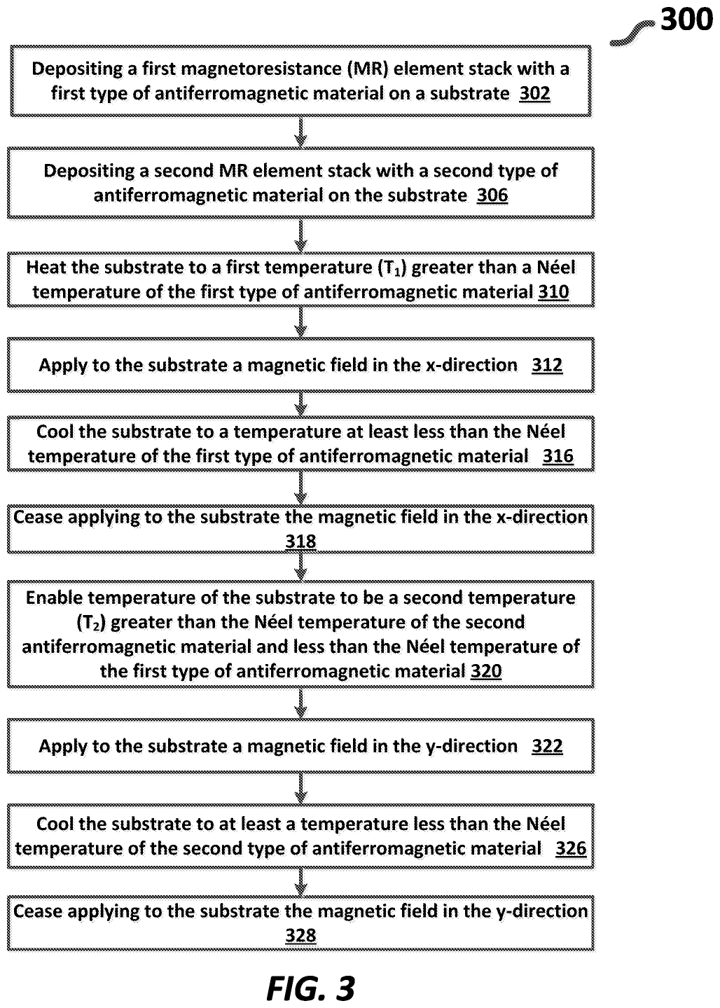

Referring to FIG. 3, an example of a process to set magnetization directions for two types of antiferromagnetic materials having different Néel temperatures from each other is a process 300. The process 300 may be used to fabricate two-dimensional angle sensors.

Process 300 deposits a first magnetoresistance (MR) element stack with a first type of antiferromagnetic material on a substrate (302). For example, the MR element stack S1 including AFM1 is deposited on the wafer 202 (FIG. 2A).

Process 300 deposits a second MR element stack with a second type of antiferromagnetic material on the substrate (306). For example, the MR element stack S2 including AFM2 is deposited on the wafer 202 (FIG. 2A).

Process 300 heats the substrate to a first temperature T₁ greater than a Néel temperature of the first type of antiferromagnetic material (310). For example, the wafer 202 is heated so that T₁ is greater than T_{N(AF1)} (FIG. 2B).

Process 300 applies to the substrate a magnetic field in the x-direction (312). For example, a magnetic field 240 in the x-direction is applied to the wafer 202 and the magnetization direction 220a of AFM1 and the magnetization direction 220b of AFM2 align with the applied magnetic field 240 and point in the x-direction (FIG. 2B).

Process 300 cools the substrate to a temperature at least less than the Néel temperature of the first type of antiferromagnetic material (316). For example, the wafer 202 cools to a temperature at least less than T_{N(AF1)} (FIG. 2B). In one example, the wafer 202 is cooled to a temperature at least less than 417° C.

Process 300 ceases applying to the substrate the magnetic field in the x-direction (318). For example, the magnetic field 240 in the x-direction is no longer applied to the wafer 202.

Process 300 enables a temperature of the substrate to be a second temperature (T₂) greater than the Néel temperature of the second type of antiferromagnetic material and less than the Néel temperature of the first type of antiferromagnetic material (320). For example, the wafer 202 is heated so that T₂ is greater than T_{N(AF2)} and less than T_{N(AF1)} (FIG. 2C).

Process 300 applies to the substrate a magnetic field in the y-direction (322). For example, a magnetic field 250 in the y-direction is applied to the wafer 202 and the magnetization direction 220b of AFM2 aligns with the applied magnetic field 250 and point in the y-direction (FIG. 2C).

Process 300 cools the substrate to a temperature at least less than the Néel temperature of the second type of antiferromagnetic material (326). For example, the wafer 202 cools to a temperature at least less than T_{N(AF2)} (FIG. 2C). In one example, the wafer 202 is cooled to a temperature at least less than 257° C.

Process 300 ceases applying to the substrate the magnetic field in the y-direction (328). For example, the magnetic field 250 in the y-direction is no longer applied to the wafer 202.

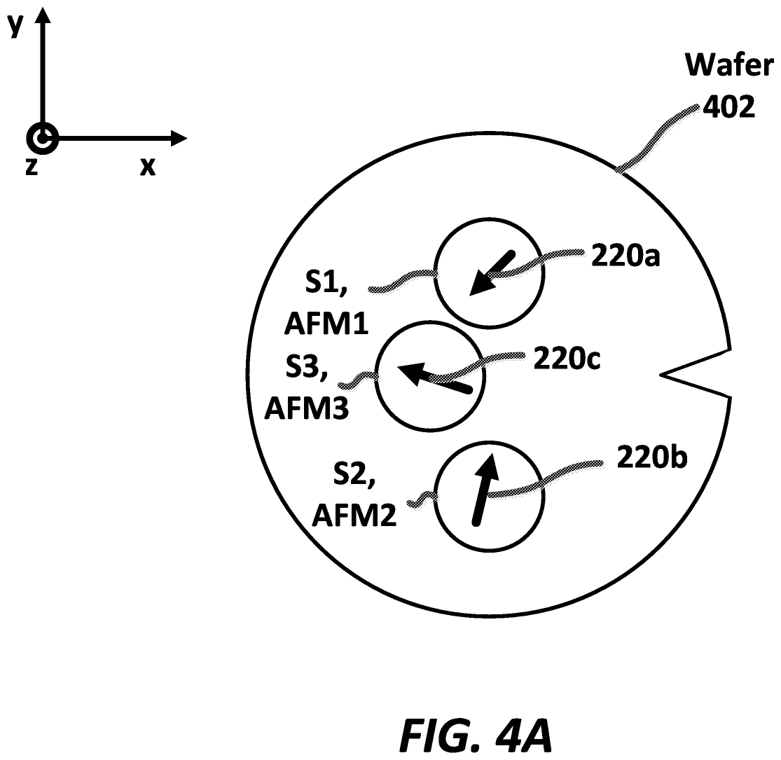

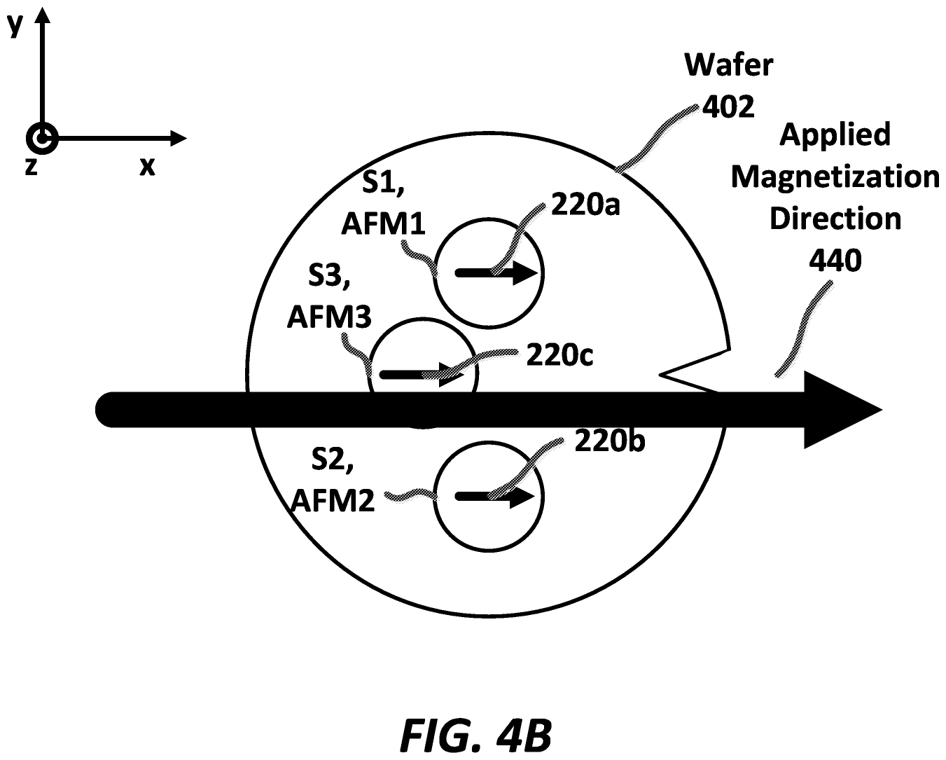

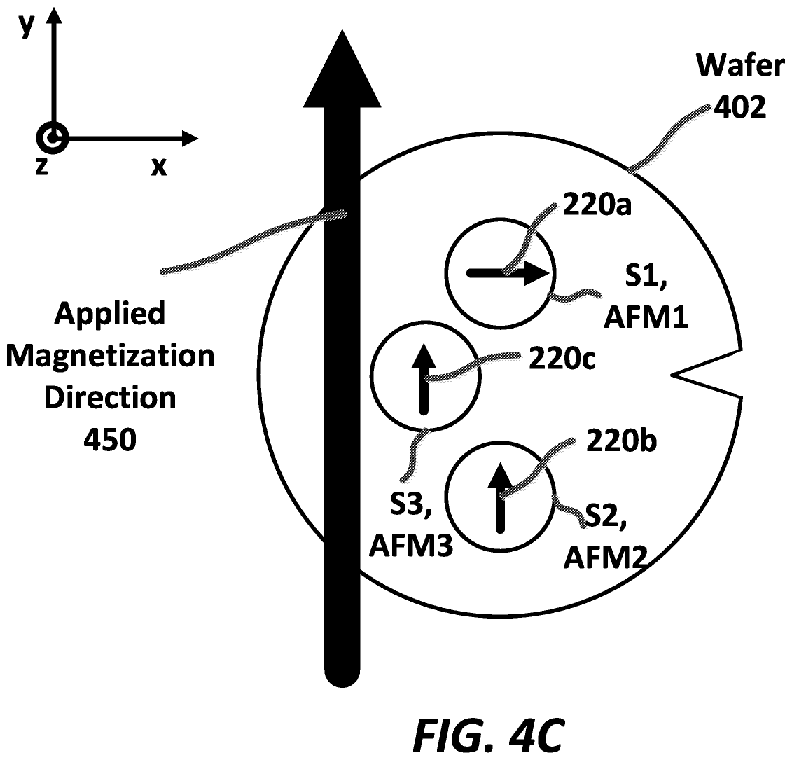

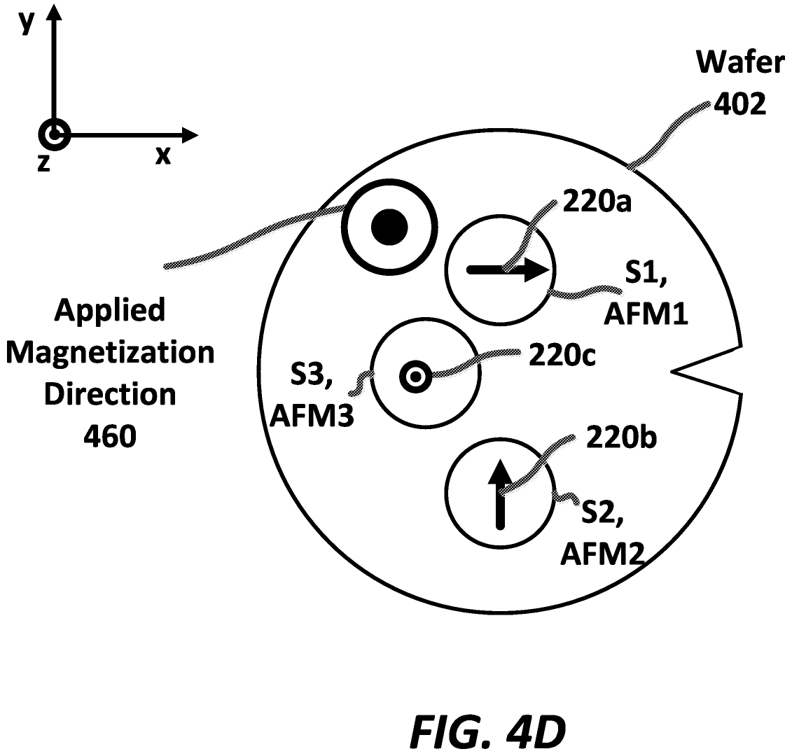

Referring to FIG. 4A, the techniques herein may also be applied to a three-dimensional angle sensor. A wafer 402 includes the first MR stack S1 with the AFM1, the second MR stack S2 with AFM2, and a third MR stack S3 with a third type of antiferromagnetic material (AFM3). The AFM3 has a Néel temperature T_{N(AF3)}, where T_{N(AF1)}>T_{N(AF2)>}T_{N(AF3)}. The AFM3 has a magnetization direction 220c.

In one example, AFM1 may be iridium manganese (IrMn), iron manganese (FeMn), or platinum manganese (PtMn). In another example, AFM2 may be iridium manganese (IrMn), iron manganese (FeMn), or platinum manganese (PtMn). In a further example, AFM3 may be iridium manganese (IrMn), iron manganese (FeMn), or platinum manganese (PtMn). The examples in the paragraph are limited to T_{N(AF1)}>T_{N(AF2)>}T_{N(AF3)}.

Referring to FIG. 4B, after heating the wafer 402 to a first temperature greater than T_{N(AF1)}, a magnetic field 440 is applied to the wafer 402 in the x-direction. The magnetization direction 220a of AFM1, the magnetization direction 220b of AFM2, and the magnetization direction 220c of AFM3 align with the applied magnetic field 440 and point in the x-direction.

Referring to FIG. 4C, after cooling the wafer 402 and after enabling the temperature of the wafer 402 to be a second temperature greater than T_{N(AF2)} and less than T_{N(AF1)}, a magnetic field 450 is applied to the wafer 402 in the y-direction. The magnetization direction 220b of AFM2 and the magnetization direction 220c of AFM3 align with the applied magnetic field 450 and point in the y-direction.

Referring to FIG. 4D, after cooling the wafer 402 and after enabling the temperature of the wafer 402 to be a third temperature greater than T_{N(AF3)} and less than T_{N(AF2)}, a magnetic field 460 is applied to the wafer 402 in the z-direction. The magnetization direction 220c of AFM3 aligns with the applied magnetic field 460 and point in the z-direction.

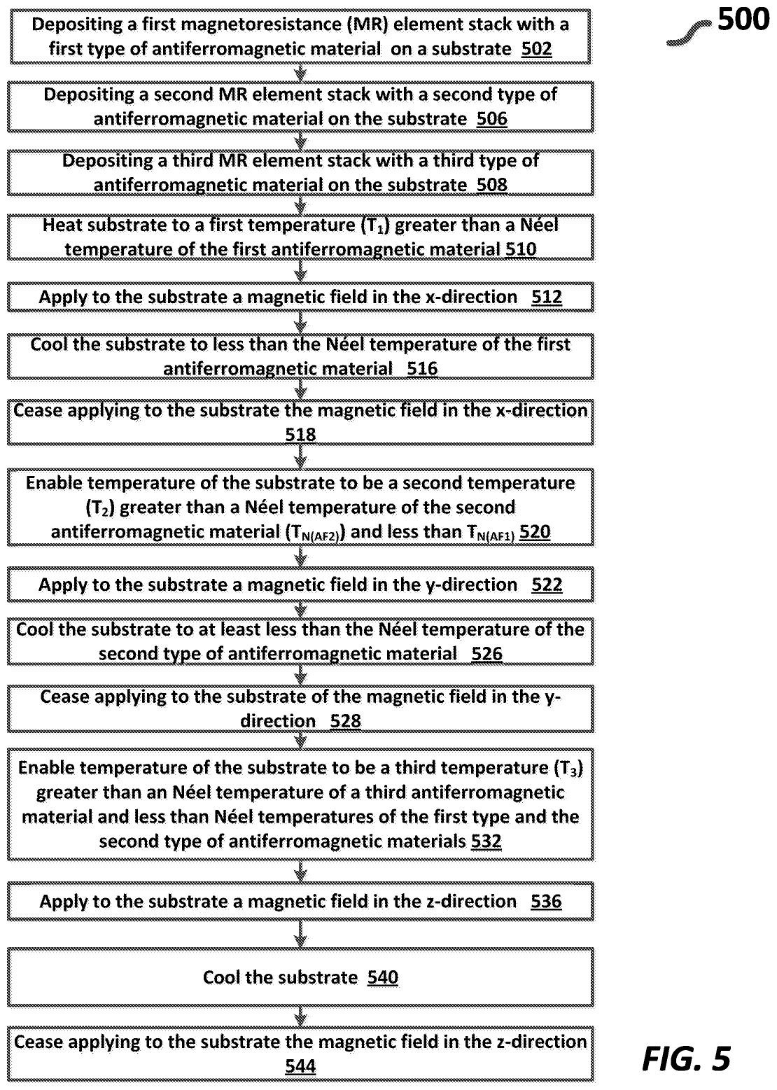

Referring to FIG. 5, an example of a process to set magnetization directions for three types of antiferromagnetic materials having different Néel temperatures from each other is a process 500. The process 500 may be used to fabricate three-dimensional angle sensors.

Process 500 deposits a first magnetoresistance (MR) element stack with a first type of antiferromagnetic material on a substrate (502). For example, the MR element stack S1 including AFM1 is deposited on the wafer 402 (FIG. 4A).

Process 500 deposits a second MR element stack with a second type of antiferromagnetic material on the substrate (506). For example, the MR element stack S2 including AFM2 is deposited on the wafer 402 (FIG. 4A).

Process 500 deposits a third MR element stack with a third type of antiferromagnetic material on the substrate (508). For example, the MR element stack S3 including AFM3 is deposited on the wafer 402 (FIG. 4A).

Process 500 heats the substrate to a first temperature T₁ greater than a Néel temperature of the first type of antiferromagnetic material (510). For example, the wafer 402 is heated so that T₁ is greater than T_{N(AF1)} (FIG. 4B).

In other examples, additional stacks with AFM1, AFM2, AFM3 may be included so that one or more x-bridges, one or more y-bridges and one or more z-bridges may be formed. For example, stacks with AFM1 may be used to form x-bridges, stacks with AFM2 may be used to form y-bridges and stacks with AFM3 may be used to form one or more z-bridges.

Process 500 applies to the substrate a magnetic field in the x-direction (512). For example, an applied magnetic field 440 in the x-direction is applied to the wafer 402 and the magnetization direction 220a of AFM1, the magnetization direction 220b of AFM2 and the magnetization direction 220c of AFM3 align with the applied magnetic field 440 and point in the x-direction (FIG. 4B).

Process 500 cools the substrate to a temperature at least less than the Néel temperature of the first type of antiferromagnetic material (516). For example, the wafer 402 is cooled to a temperature at least less than T_{N(AF1)} (FIG. 4B). In one example, the wafer 402 is cooled to a temperature at least less than 417° C.

Process 500 ceases applying to the substrate the magnetic field in the x-direction (518). For example, the magnetic field 440 in the x-direction is no longer applied to the wafer 402.

Process 500 enables a temperature of the substrate to be a second temperature (T₂) greater than the Néel temperature of the second type of antiferromagnetic material and less than the Néel temperature of the first type of antiferromagnetic material (520). For example, the wafer 402 is heated so that T₂ is greater than T_{N(AF2)} but less than T_{N(AF1)} (FIG. 4C).

Process 500 applies to the substrate a magnetic field in the y-direction (522). For example, an applied magnetic field 450 in the y-direction is applied to the wafer 402 and the magnetization direction 220b of AFM2 and the magnetization direction 220c of AMF3 align with the applied magnetic field 250 and point in the y-direction (FIG. 4C).

Process 500 cools the substrate to a temperature at least less than the Néel temperature of the second type of antiferromagnetic material (526). For example, the wafer 402 cools to a temperature at least less than T_{N(AF2)} (FIG. 4C). In one example, the wafer 402 is cooled to a temperature at least less than 257° C.

Process 500 ceases applying to the substrate the magnetic field in the y-direction (528). For example, the applied magnetic field 450 in the y-direction is no longer applied to the wafer 402.

Process 500 enables temperature of the substrate to be a third temperature (T₃) greater than an Néel temperature of a third antiferromagnetic material and less than Néel temperatures of the first type and the second type of antiferromagnetic materials (532). For example, the wafer 402 is heated so that T₃ is greater than T_{N(AF3)}, but less than T_{N(AF2)} and less than T_{N(AF1)} (FIG. 4C).

Process 500 applies to the substrate a magnetic field in the z-direction (536). For example, a magnetic field 460 in the y-direction is applied to the wafer 402 and the magnetization direction 220c of AFM3 aligns with the applied magnetic field 460 and point in the z-direction (FIG. 4D).

Process 500 cools the substrate to a temperature at least less than the Néel temperature of the third type of antiferromagnetic material (540). For example, the wafer 402 cools to a temperature at least less than T_{N(AF3)} (FIG. 4D). In one example, the wafer 402 is cooled to a temperature at least less than 217° C.

Process 500 ceases applying to the substrate the magnetic field in the z-direction (544). For example, the applied magnetic field 460 in the z-direction is no longer applied to the wafer 402.

The processes described herein are not limited to the specific examples described. For example, the processes 300 and 500 are not limited to the specific processing order of FIGS. 3 and 5, respectively. Rather, any of the processing blocks of FIGS. 3 and 5 may be re-ordered, combined, or removed, performed in parallel or in serial, as necessary, to achieve the results set forth above.

Bridges (e.g., x-bridge, y-bridge, z-bridge) include at least four MR elements. MR elements in a bridge may include TMR elements and/or GMR elements. The processes (e.g., the process 300, the process 500) may be used to form one or more of the MR elements in a bridge. In one particular example, the processes (e.g., the process 300, the process 500) may be used to form all of the MR elements in a bridge.

In other examples, in the processes 300 and 500, the MR element stack may be heated to a temperature less than the Néel temperature of an antiferromagnetic material. In particular, the temperature at which there exists no exchange biasing is known as the blocking temperature, Tb. This temperature is below the Néel temperature, Tn. At T=Tb, the FM layer is not exchange biased and is free to rotate and orient its magnetic spins along any direction, but the AF layer remains ordered since Tb<Tn. Therefore, it is possible to induce a certain amount of biasing by heating the sample to a temperature greater than Tb but less than Tn and then cooling it in the presence of a field. It should be noted that cooling the wafer in the presence of a field from the Néel temperature as well as the blocking temperature naturally, allows the reorientation of the magnetization along the applied field cooling direction.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method, comprising:
manufacturing a magnetic-field angle sensor comprising:
heating, to a first temperature, a substrate comprising:
heating a first magnetoresistance (MR) element comprising a first type of antiferromagnetic material having a first Néel temperature and a first magnetization direction;
heating a second MR element comprising a second type of antiferromagnetic material having a second Néel temperature and a second magnetization direction, wherein the first Néel temperature is greater than the second Néel temperature, wherein the first temperature is greater than the first Néel temperature;
after heating the substrate to the first temperature, applying a first magnetic field to the substrate in an x-direction to enable the first magnetization direction and the second magnetization direction to be in the x-direction;
cooling the substrate to a temperature less than the first Néel temperature while applying the first magnetic field;
enabling a temperature of the substrate to be a second temperature after ceasing to apply the first magnetic field, wherein the second temperature is less than the first Néel temperature and greater than the second Néel temperature; and
applying a second magnetic field to the substrate in a y-direction to enable the second magnetization direction to be in the y-direction.

2. The method of claim 1, wherein the manufacturing further comprises cooling the substrate to a temperature less than the second Néel temperature while applying the second magnetic field.

3. The method of claim 1, wherein the manufacturing further comprises ceasing to apply the second magnetic field.

4. The method of claim 1, wherein heating, to the first temperature, the substrate further comprises heating a third MR element comprising a third type of antiferromagnetic material having a third Néel temperature and a third magnetization direction, wherein the second Néel temperature is greater than the third Néel temperature.

5. The method of claim 4, wherein applying the first magnetic field to the substrate in the x-direction to enable the first magnetization direction and the second magnetization direction to be in the x-direction comprises applying the first magnetic field to the substrate in the x-direction to enable the first magnetization direction, the second magnetization direction and the third magnetization direction to be in the x-direction.

6. The method of claim 5, wherein applying the second magnetic field to the substrate in the y-direction to enable the second magnetization direction to be in the y-direction comprises applying the second magnetic field to the substrate in the y-direction to enable the second magnetization direction and the third magnetization direction to be in the y-direction.

7. The method of claim 6, wherein the manufacturing further comprises:
cooling the substrate to a temperature less than the second Néel temperature while applying the second magnetic field;
ceasing to apply the second magnetic field;
enabling a temperature of the substrate to be a third temperature after ceasing to apply the second magnetic field, wherein the third temperature is less than the second Néel temperature and greater than the third Néel temperature; and
applying a third magnetic field to the substrate in a z-direction to enable the third magnetization direction to be in the z-direction.

8. The method of claim 7, wherein the manufacturing further comprises:
forming an x-bridge using the first MR element;
forming a y-bridge using the second MR element; and
forming a z-bridge using the third MR element.

9. The method of claim 8, wherein the first MR element is a giant magnetoresistance (GMR) element and/or a tunneling magnetoresistance (TMR) element,
wherein the second MR element is a GMR element and/or a TMR element, and
wherein the third MR element is a GMR element and/or a TMR element.

10. The method of claim 9, wherein the MR elements of the x-bridge, the y-bridge and the z-bridge are GMR elements and/or TMR elements.

11. The method of claim 1, wherein the manufacturing further comprises:
forming an x-bridge using the first MR element; and
forming a y-bridge using the second MR element.

12. The method of claim 11, wherein the first MR element is a giant magnetoresistance (GMR) element and/or a tunneling magnetoresistance (TMR) element, and
wherein the second MR element is a GMR element and/or a TMR element.

13. The method of claim 12, wherein the MR elements of the x-bridge and the y-bridge are GMR elements and/or TMR elements.

14. A magnetic-field angle sensor comprising:
a first bridge comprising magnetoresistance (MR) elements each comprising a first type of antiferromagnetic material having a first Néel temperature and a first magnetization direction; and
a second bridge comprising MR elements comprising a second type of antiferromagnetic material having a second Néel temperature and a second magnetization direction,
wherein the first magnetization direction is orthogonal to the second magnetization direction, and
wherein the first Néel temperature is higher than the second Néel temperature.

15. The magnetic-field angle sensor of claim 14, further comprising a third bridge comprising MR elements comprising a third type of antiferromagnetic material having a third Néel temperature and a third magnetization direction,
wherein the third magnetization direction is orthogonal to the second magnetization direction, and
wherein the second Néel temperature is higher than the third Néel temperature.

16. The magnetic-field angle sensor of claim 15, wherein the first MR element is a giant magnetoresistance (GMR) element and/or a tunneling magnetoresistance (TMR) element,
wherein the second MR element is a GMR element and/or a TMR element, and
wherein the third MR element is a GMR element and/or a TMR element.

17. The magnetic-field angle sensor of claim 14, wherein the first MR element is a giant magnetoresistance (GMR) element and/or a tunneling magnetoresistance (TMR) element, and
wherein the second MR element is a GMR element and/or a TMR element.

18. The magnetic-field angle sensor of claim 17, wherein the MR elements of the first bridge and the second bridge are GMR elements and/or TMR elements.

19. A method, comprising:
manufacturing a magnetic-field angle sensor comprising:
heating, to a first temperature, a substrate comprising:
heating a first magnetoresistance (MR) element comprising a first type of antiferromagnetic material having a first blocking temperature and a first magnetization direction;
heating a second MR element comprising a second type of antiferromagnetic material having a second blocking temperature and a second magnetization direction, wherein the first blocking temperature is greater than the second blocking temperature, wherein the first temperature is greater than the first blocking temperature;
after heating the substrate to the first temperature, applying a first magnetic field to the substrate in an x-direction to enable the first magnetization direction and the second magnetization direction to be in the x-direction;
cooling the substrate to a temperature less than the first blocking temperature while applying the first magnetic field;
enabling a temperature of the substrate to be a second temperature after ceasing to apply the first magnetic field, wherein the second temperature is less than the first blocking temperature and greater than the second blocking temperature; and
applying a second magnetic field to the substrate in a y-direction to enable the second magnetization direction to be in the y-direction.

20. The method of claim 19, wherein the manufacturing further comprises cooling the substrate to a temperature less than the second blocking temperature while applying the second magnetic field.

21. The method of claim 19, wherein the manufacturing further comprises ceasing to apply the second magnetic field.

22. The method of claim 19, wherein heating, to the first temperature, the substrate further comprises heating a third MR element comprising a third type of antiferromagnetic material having a third blocking temperature and a third magnetization direction, wherein the second blocking temperature is greater than the third blocking temperature,
wherein applying the first magnetic field to the substrate in the x-direction to enable the first magnetization direction and the second magnetization direction to be in the x-direction comprises applying the first magnetic field to the substrate in the x-direction to enable the first magnetization direction, the second magnetization direction and the third magnetization direction to be in the x-direction, and
wherein applying the second magnetic field to the substrate in the y-direction to enable the second magnetization direction to be in the y-direction comprises applying the second magnetic field to the substrate in the y-direction to enable the second magnetization direction and the third magnetization direction to be in the y-direction.

23. The method of claim 22, wherein the manufacturing further comprises:
cooling the substrate to a temperature less than the second blocking temperature while applying the second magnetic field;
ceasing to apply the second magnetic field;
enabling a temperature of the substrate to be a third temperature after ceasing to apply the second magnetic field, wherein the third temperature is less than the second blocking temperature and greater than the third blocking temperature; and
applying a third magnetic field to the substrate in a z-direction to enable the third magnetization direction to be in the z-direction.

24. The method of claim 23, wherein the manufacturing further comprises:
forming an x-bridge using the first MR element;
forming a y-bridge using the second MR element; and
forming a z-bridge using the third MR element.

25. The method of claim 24, wherein the first MR element is a giant magnetoresistance (GMR) element and/or a tunneling magnetoresistance (TMR) element,
wherein the second MR element is a GMR element and/or a TMR element, and
wherein the third MR element is a GMR element and/or a TMR element.

26. The method of claim 25, wherein the MR elements of x-bridge, the y-bridge and the z-bridge are GMR elements and/or TMR elements.

27. The method of claim 19, wherein the manufacturing further comprises:
forming an x-bridge using the first MR element; and
forming a y-bridge using the second MR element.

28. The method of claim 27, wherein the first MR element is a giant magnetoresistance (GMR) element and/or a tunneling magnetoresistance (TMR) element, and
wherein the second MR element is a GMR element and/or a TMR element.

29. The method of claim 28, wherein the MR elements of the x-bridge and the y-bridge are GMR elements and/or TMR elements.
